(19) United States
(12) Patent Application Publication
(10) Pub. No.: US 2007/0141798 A1
(43) Pub. Date: Jun. 21, 2007

(54) Silicide layers in contacts for high-k/metal gate transistors

(75) Inventor: Mark T. Bohr, Aloha, OR (US)

Correspondence Address: INTEL CORPORATION;c/o INTELLEVATE, LLC, P.O. BOX 52050, MINNEAPOLIS, MN, 55402, US

(73) Assignee: Intel Corporation

(21) Appl. No.: 11/314,362

(22) Filed: Dec. 20, 2005

(51) Int. Cl. H01L 21/336

(52) U.S. Cl. 438/301

(57) ABSTRACT

A method for forming metal silicide layers in a high-k/metal gate transistor comprises forming a transistor with a sacrificial gate on a substrate, depositing a first ILD layer on the substrate, removing the sacrificial gate to form a gate trench, depositing a high-k dielectric layer within the gate trench, annealing the high-k dielectric layer, depositing a first metal layer within the gate trench, depositing a second ILD layer on the first ILD layer and the transistor, etching the first and second ILD layers to form a first contact trench and a second contact trench that extend down to a source region and a drain region of the transistor, depositing a second metal layer within the contact trenches, annealing the second metal layer to form metal silicide layers, and depositing a third metal layer within the first and second contact trenches to fill the contact trenches.

### BACKGROUND

Metal oxide semiconductor (MOS) field-effect transistors with very thin gate dielectrics made from silicon dioxide (SiO₂) may experience unacceptable gate leakage currents. Forming the gate dielectric from certain high-k dielectric materials instead of SiO₂ can reduce gate leakage, however, high-k dielectric materials may not be compatible with polysilicon. Therefore it may be desirable to use metal gate electrodes in devices that include high-k gate dielectric layers, as metal gate electrodes are compatible with high-k gate dielectrics and provide high performance relative to polysilicon. Such high-k/metal gate transistors may be further improved by using metal silicide layers to couple electrical contacts to the source and drain regions of the transistor. The metal silicide layer reduces electrical resistance between the electrical contacts and the source and drain regions.

When a high-k dielectric layer is initially formed, it may have a slightly imperfect molecular structure. To repair such a film, it may be necessary to anneal it at a relatively high temperature. In addition, annealing the high-k dielectric layer improves transistor reliability. Unfortunately, the metals or alloys used in metal gate electrode and the metal silicide layers cannot tolerate the high temperatures necessary to anneal the high-k dielectric layer. Therefore, process flows are needed whereby the high-k gate dielectric layer may be annealed without damaging the metal gate electrode and the metal silicide layers.

### BRIEF DESCRIPTION OF THE DRAWINGS

FIGS. 1 through 4 illustrate structures that may be formed when building a conventional transistor.

FIG. 5 is a method for building a high-k/metal gate transistor with metal silicide layers in accordance with an implementation of the invention.

FIGS. 6 through 13 illustrate structures that may be formed when building a high-k/metal gate transistor with metal silicide layers in accordance with an implementation of the invention.

FIG. 14 illustrates contact trenches.

FIG. 15 illustrates contact vias.

### DETAILED DESCRIPTION

Described herein are systems and methods of forming nickel silicide layers for transistors with a high-k gate dielectric and a metal gate. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

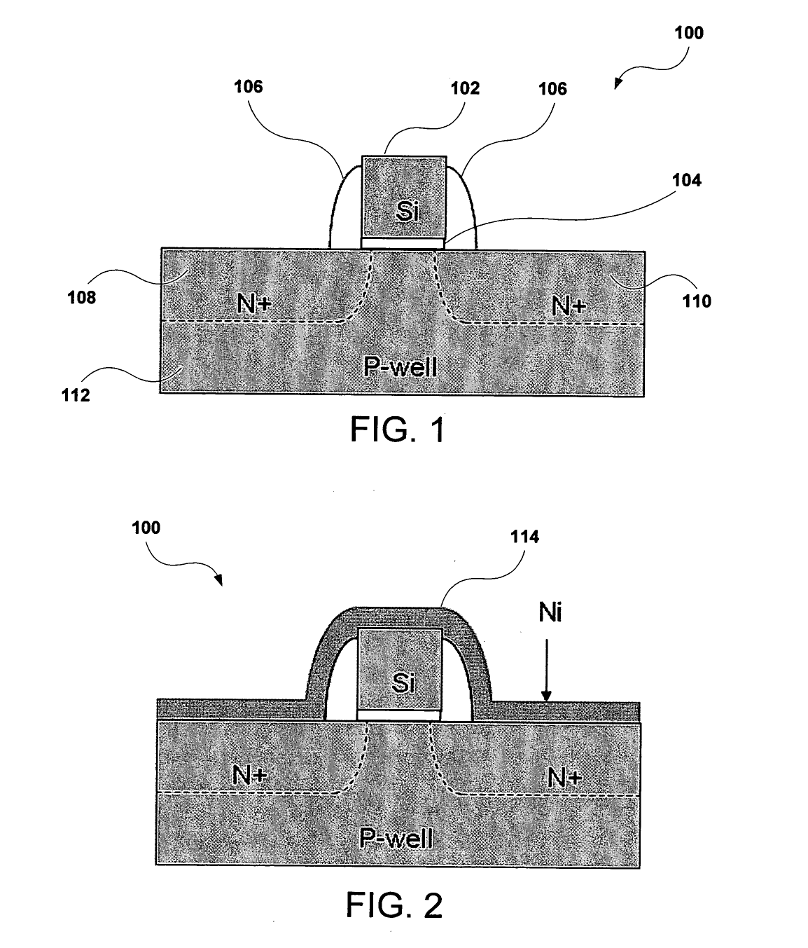

In conventional transistors, metal silicide layers may be used to couple electrical contacts to the source and drain regions of a transistor. The metal silicide tends to reduce electrical resistance between the source/drain regions of the transistor and the electrical contacts that are made to them. FIGS. 1 through 4 illustrate one process for forming nickel silicide layers on a conventional transistor.

FIG. 1 illustrates a conventional transistor 100 that includes a gate electrode 102, a gate oxide 104, pair of spacers 106, a source region 108, and a drain region 110. The transistor 100 is formed on a substrate 112, such as a semiconductor wafer. As shown, a region below the transistor 100 may be P-doped and the source and drain regions may be N-doped. Alternately, the region below the transistor 100 may be N-doped and the source and drain regions may be P-doped.

The gate oxide 104 is disposed between the spacers 106 and may be formed from silicon dioxide (SiO₂) that is thermally grown. The gate electrode 102 may be formed by depositing and patterning a layer of polysilicon. Conventional photolithography techniques may be used to pattern the polysilicon to form the gate electrode 102. The source region 108 and drain region 110 may be formed by implanting dopants into regions of the substrate surface 112 that are adjacent to the spacers 106. Dopants that may be used to form the source and drain regions 108/110 are well known in the art. A high temperature annealing process may be used to activate the dopants to complete formation of the source and drain regions 108/110.

FIG. 2 illustrates a nickel layer 114 that has been deposited upon the transistor 100. Conventional metal deposition processes, such as a sputtering deposition process, may be used to form the nickel layer 114. An annealing process may then be carried out to cause the nickel metal to react with certain portions of the transistor 100 and form nickel silicide layers. Any unreacted nickel metal may be selectively removed using known processes.

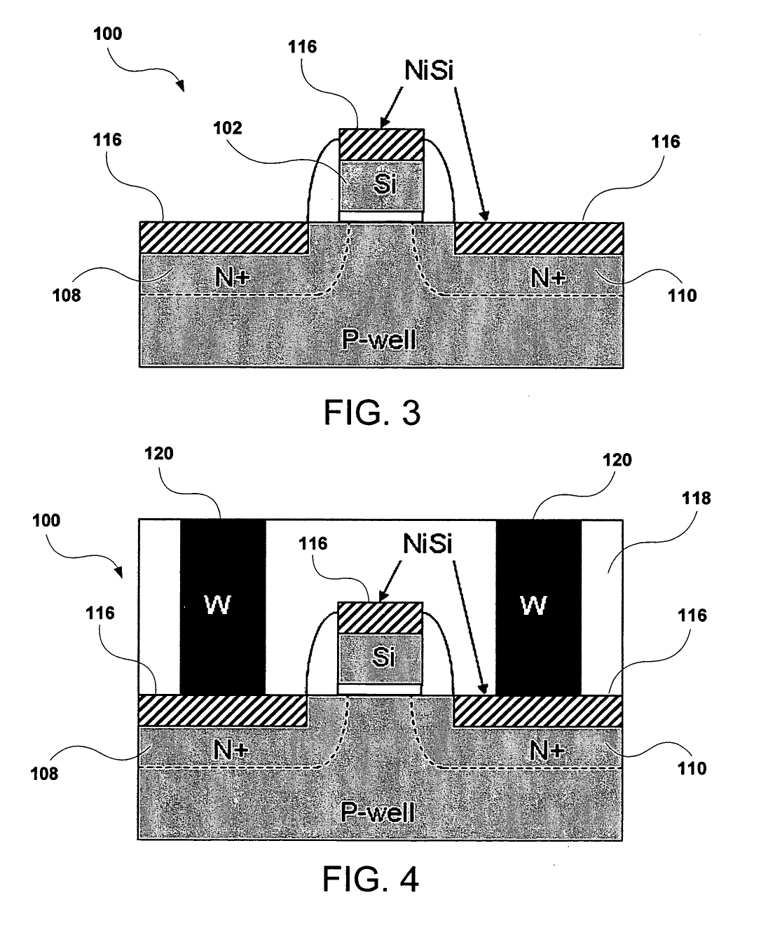

FIG. 3 illustrates the result of the annealing process. Nickel silicide layers 116 are formed over certain areas of the transistor 100. For instance, the nickel metal 114 will react to form nickel silicide layers 116 that completely cover the source and drain regions 108/110. The nickel metal 114 will also react to form a nickel silicide layer 116 over the gate electrode 102.

Finally, as shown in FIG. 4, a thick dielectric layer 118 may be deposited over the transistor 100 and the nickel silicide layers 116. Electrical contacts 120 may then be formed within the dielectric layer 118. The dielectric layer 118 may be formed using conventional dielectric materials such as silicon dioxide or carbon doped oxide. The electrical contacts 120 may be formed by first etching discrete contact vias into the dielectric layer 118 that are aligned with the source and drain regions 108/110, and then filling the vias with a metal such as tungsten (FIG. 15 illustrates a top view of discrete contact vias 626). The electrical contacts 120 couple the transistor 100 to interconnects and other devices (not shown). The nickel silicide layers 116 reduce the electrical resistance between the electrical contacts 120 and the source and drain regions 108/110.

As transistor dimensions decrease, there has been a shift to using high-k dielectric materials within the gate stack of a transistor. High-k dielectric materials have been found to reduce the gate leakage that occurs as transistors are scaled down in size and gate dielectrics become thinner. Generally, high-k dielectric materials have dielectric constants around 3.9 or higher and are often hafnium (Hf)-based or zirconium (Zr)-based. Some examples of high-k dielectric materials include, but are not limited to, Al₂O₃, ZrO₂, barium strontium titanate (BST), lead zirconate titanate (PZT), ZrSiO₂, HfSiO₂, HfSiON, TaO₂, and HfO₂. Metal gates must be used with the high-k gate dielectrics as polysilicon is generally incompatible with the high-k dielectric material.

Unfortunately, high-k gate dielectric materials must be annealed at relatively high temperatures to maximize their performance and reliability. These relatively high annealing temperatures may damage metal layers, such as metal gates or metal silicide layers. For instance, as described above, nickel silicide is often used to cover source regions and drain regions to provide lower resistance when electrical contacts are made to the transistor. Nickel silicide, however, cannot tolerate temperatures above 400° C. that are needed to anneal the high-k dielectric material.

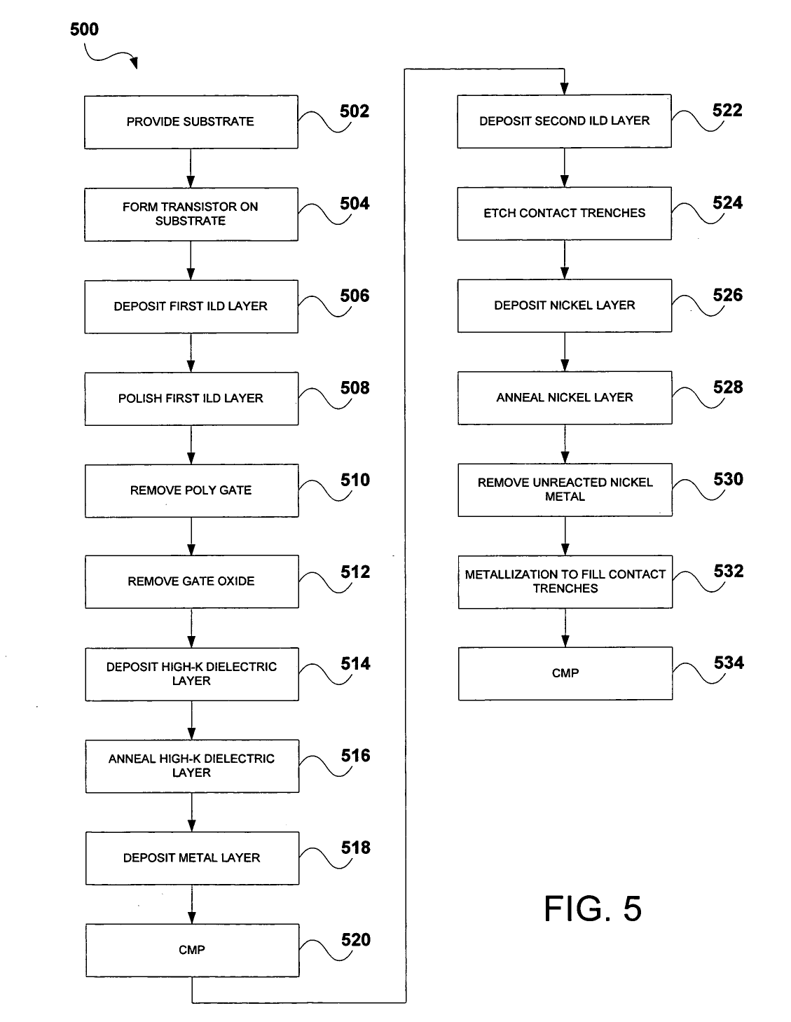

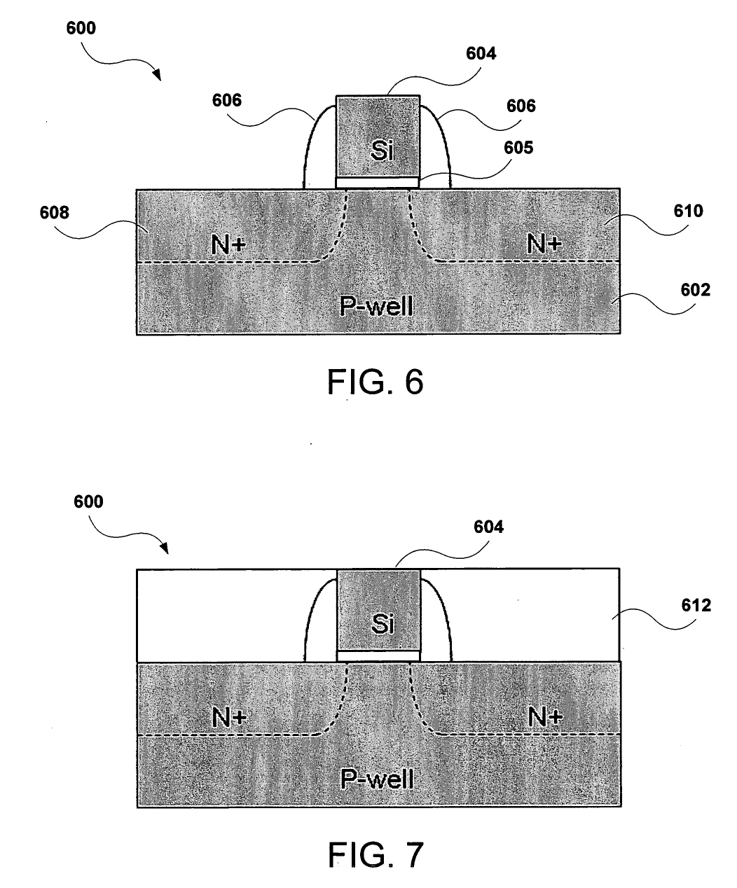

In accordance with implementations of the invention, FIG. 5 demonstrates a process 500 for forming a high-k/metal gate transistor with metal silicide layers on the source and drain regions, where the high-k gate dielectric has been annealed. FIGS. 6 through 13 illustrate structures that are formed while carrying out the process 500 of FIG. 5. In the discussion of process 500 below, FIGS. 6 through 13 will be referenced to illustrate the various stages of the process.

First, a substrate is provided upon which the high-k/metal gate transistor of the invention may be formed (502 of FIG. 5). The substrate may be formed using a bulk silicon or a silicon-on-insulator (SOI) substructure. In other implementations, the substrate may be formed using alternate materials, which may or may not be combined with silicon, that include but are not limited to germanium, indium antimonide, lead telluride, indium arsenide, indium phosphide, gallium arsenide, or gallium antimonide. Although a few examples of materials from which the substrate may be formed are described here, any material that may serve as a foundation upon which a semiconductor device may be built falls within the spirit and scope of the present invention.

Next, a transistor that includes at least a sacrificial polysilicon gate, a gate oxide, a pair of spacers, a source region, and a drain region may be formed on the substrate (504). Techniques and processes for forming transistors are well known in the art. For instance, the gate oxide may be thermally grown and the sacrificial polysilicon gate may be formed by depositing and etching a polysilicon layer atop the gate oxide. The spacers may be formed on opposing sides of the polysilicon gate using conventional materials such as silicon nitride. Regions of the substrate surface adjacent to each of the spacers may be implanted with dopants and annealed to form a source region and a drain region. In some implementations the source and drain regions may consist of N-type regions on a P-type well, while in other implementations the source and drain regions may consist of P-type regions on an N-type well. A variety of dopants may be used to form the source and drain regions, which are well known in the art. For example, dopants such as arsenic, phosphorous, and/or antimony may be used to form N-type regions, while dopants such as boron and/or aluminum may be used to form P-type regions.

FIG. 6 illustrates a transistor 600 formed upon a substrate 602. The transistor 600 includes a polysilicon gate electrode 604, a gate oxide 605, a pair of spacers 606, a source region 608, and a drain region 610. The substrate 602 may further include isolation structures (not shown). Such isolation structures may include, but are not limited to, ILDs such as carbon doped oxide (CDO) or silicon dioxide (SiO₂), shallow trench isolation structures (STI), or other materials that may separate the active regions of adjacent transistors. Methods for forming the isolation structures are well known in the art.

A first interlayer dielectric (ILD layer) may be deposited over the conventional transistor (506). The first ILD layer may be formed using any of a variety of conventional dielectric materials used in forming interlayer dielectrics. Such dielectric materials include, but are not limited to, oxides such as silicon dioxide (SiO₂) and carbon doped oxide (CDO), silicon nitride, organic polymers such as perfluorocyclobutane (PFCB), or fluorosilicate glass (FSG). The first ILD layer may be deposited using vapor deposition processes such as chemical vapor deposition (CVD), atomic layer deposition (ALD), or plasma enhanced chemical vapor deposition (PECVD). Alternately, the first dielectric layer may be formed using epitaxial processes.

The first ILD layer may be polished back or planarized until a top surface of the sacrificial polysilicon gate is exposed (508). A chemical mechanical polishing (CMP) process may be used to planarize the first ILD layer and expose the sacrificial polysilicon gate. In some implementations, the CMP process may overpolish the ILD layer to ensure that the sacrificial polysilicon gate is exposed. FIG. 7 illustrates the first ILD layer 612 after it has been deposited over the transistor 600 and polished back until the top surface of the gate 604 is exposed.

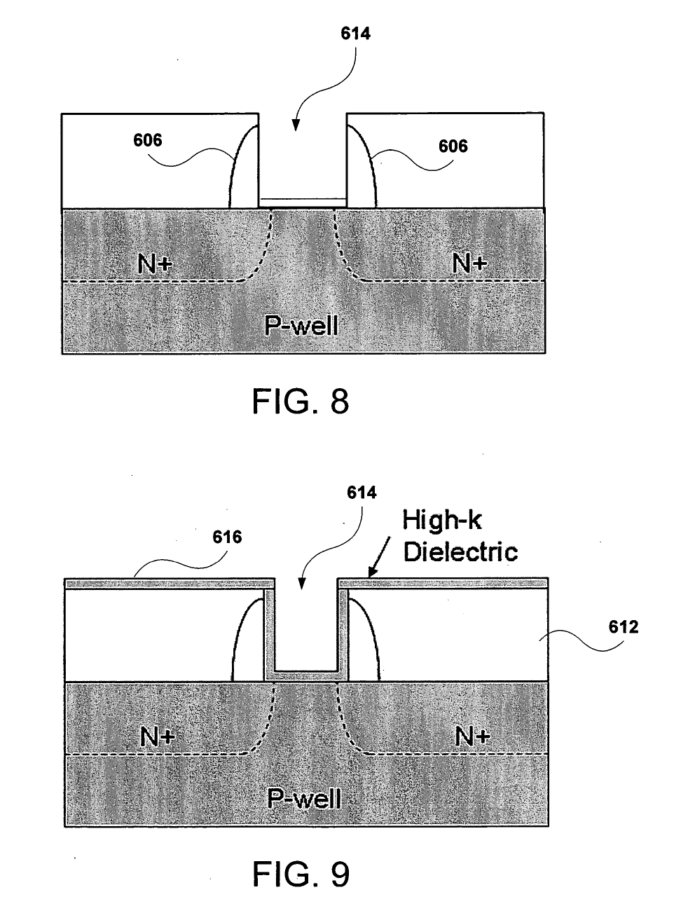

Next, the sacrificial polysilicon gate may be removed (510). A gate trench is left between the spacers when the sacrificial polysilicon gate is removed. In some implementations of the invention, a wet etch process or a dry etch process targeted for polysilicon may be used to remove the sacrificial polysilicon gate. FIG. 8 illustrates the transistor 600 after the gate 604 has been etched out, leaving behind a gate trench 614 between the pair of spacers 606.

In some implementations, a wet etch process may be used that exposes the sacrificial polysilicon gate to an aqueous solution consisting of a source of hydroxide. The wet etch may be applied for a sufficient time and at a sufficient temperature to remove substantially all of the sacrificial polysilicon gate. For example, in one implementation, the source of hydroxide may contain between about 1 and about 40 percent ammonium hydroxide or a tetraalkyl ammonium hydroxide, e.g., tetramethyl ammonium hydroxide (TMAH), by volume in deionized water. The temperature of the solution may be maintained at a temperature between about 15° C. and about 90° C. (e.g., 40° C.) and the exposure time may range from 0 to 60 minutes (e.g., 1 minute). As will be recognized by those of skill in the art, the exact constituents of the etching solution may vary from those presented herein.

In alternate implementations of the invention, a dry etch process may be used to selectively remove the sacrificial polysilicon gate. The dry etch process may comprise exposing the sacrificial polysilicon gate to a plasma derived from materials that include, but are not limited to, sulfur hexafluoride (SF₆), hydrogen bromide (HBr), hydrogen iodide (HI), chlorine, argon, and/or helium. Such a selective dry etch process may take place in a parallel plate reactor or in an electron cyclotron resonance etcher. The plasma etch used to remove the polysilicon gate may be the same process that was used to pattern the polysilicon gate in the first place.

If a gate oxide is present below the sacrificial polysilicon gate, such as the gate oxide 605 shown in FIG. 6, it may be removed as well (512). In some implementations, a hydrogen fluoride (HF) etchant or a conventional wet etchant may be used to remove the gate oxide.

Next, a high-k gate dielectric layer may be conformally deposited atop the first ILD layer and within the gate trench left by removing the sacrificial polysilicon gate and the gate oxide (514). FIG. 9 illustrates the deposition of a conformal high-k dielectric layer 616 atop the first ILD layer 612 and within the gate trench 614. As shown in FIG. 9, the conformal deposition of the high-k gate dielectric layer 616 may cover the sidewalls and bottom of the gate trench 614. The high-k gate dielectric layer 616 may be formed using materials that include, but are not limited to, hafnium oxide, hafnium silicon oxide, hafnium silicon oxynitride, lanthanum oxide, zirconium oxide, zirconium silicon oxide, tantalum oxide, titanium oxide, barium strontium titanium oxide, BST, barium titanium oxide, strontium titanium oxide, yttrium oxide, aluminum oxide, lead scandium tantalum oxide, lead zinc niobate, and PZT. Although a few examples of materials that may be used to form high-k gate dielectric layer are described here, that layer may be formed using other materials that serve to reduce gate leakage.

In some implementations, the high-k gate dielectric layer may be formed on the substrate using a conventional deposition process, including but not limited to CVD, low pressure CVD, PECVD, physical vapor deposition (PVD), ALD, spin-on dielectric processes (SOD), or epitaxial growth. In one implementation of the invention, an ALD process may be used where a metal oxide precursor (e.g., a metal chloride) and steam may be fed at selected flow rates into a CVD reactor, which may be operated at a selected temperature and pressure to generate an atomically smooth interface between the substrate and the high-k gate dielectric layer. The CVD reactor may be operated long enough to form a layer with the desired thickness. In some implementations, the thickness of the resulting high-k gate dielectric layer may range from 3 Angstroms (Å) to 60 Å, and more preferably range from around 5 Å to around 40 Å.

An annealing process may then be carried out on the structure (516). In some implementations, the annealing process may be a rapid thermal anneal that takes place at a temperature within the range of 600° C. to 800° C. for a time period within the range of 0.5 seconds to 10 seconds. Such an anneal may modify the molecular structure of high-k gate dielectric layer to create an annealed gate dielectric layer that may demonstrate improved process control and reliability, resulting in improved device performance.

A metallization process may then be carried out to deposit a metal layer onto the annealed high-k gate dielectric layer (518). The metal deposition covers the annealed high-k gate dielectric layer and fills the gate trench with metal. The metal layer will generally have a thickness that ranges from 100 Å to 2000 Å. Well known metal deposition processes, such as CVD, PVD, ALD, sputtering, electroplating, or electroless plating, may be used to deposit the metal layer. The metal that is deposited will form the metal gate electrode, therefore, metals that may be used in the metallization process include metals or metal alloys that are conventionally used for metal gate electrodes. For instance, the metal used may be one or a combination of the following metals: copper, ruthenium, palladium, platinum, cobalt, nickel, ruthenium oxide, tungsten, aluminum, titanium, tantalum, titanium nitride, tantalum nitride, hafnium, zirconium, a metal carbide, or a conductive metal oxide. In other implementations, metals not listed here may be used. In some implementations of the invention, the metal used may be a combination of a workfunction metal and a trench fill metal.

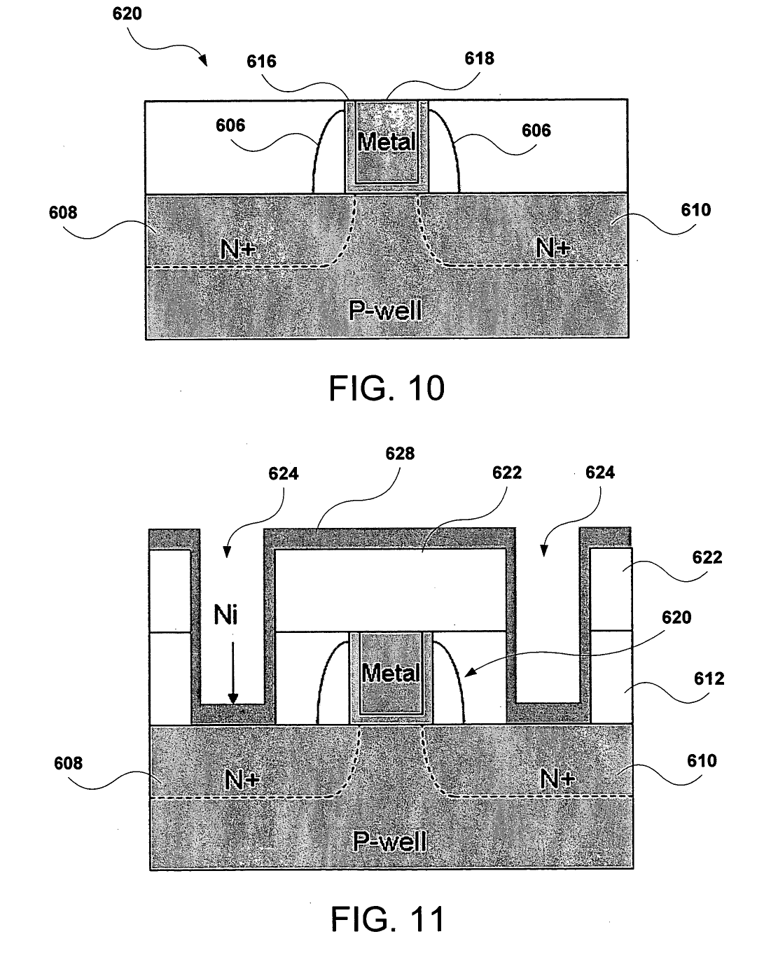

Next, a CMP process may be used to planarize the deposited metal and complete the formation of a high-k/metal gate transistor (520). The CMP process removes excess portions of the metal and excess portions of the annealed high-k gate dielectric layer. FIG. 10 illustrates a metal gate 618 that is formed within the high-k dielectric layer 616 after the CMP process is used to planarize the deposited metal. The combination of at least the metal gate 618, the high-k dielectric layer 616, the spacers 606, the source region 608, and the drain region 610 forms a high-k/metal gate transistor 620.

A second ILD layer may then be deposited over the first dielectric layer and the high-k/metal gate transistor (522). Like the first ILD layer, the second ILD layer may be formed using any of a variety of conventional ILD materials, such as SiO₂, CDO, silicon nitride, PFCB, or FSG. The second ILD layer may be deposited using processes such as CVD, ALD, PECVD, or epitaxial processes. FIG. 11 illustrates a second ILD layer 622 that is deposited over the first ILD layer 612 and the high-k/metal gate transistor 620.

Contact trenches may then be etched through the first and second dielectric layers that extend down to the source and drain regions (524). FIG. 11 illustrates such contact trenches 624 that have been etched through the second dielectric layer 622 and the first dielectric layer 612 and that stop on the source region 608 and the drain region 610. It is within the contact trenches 624 that electrical contacts to the high-k/metal gate transistor 620 will be formed.

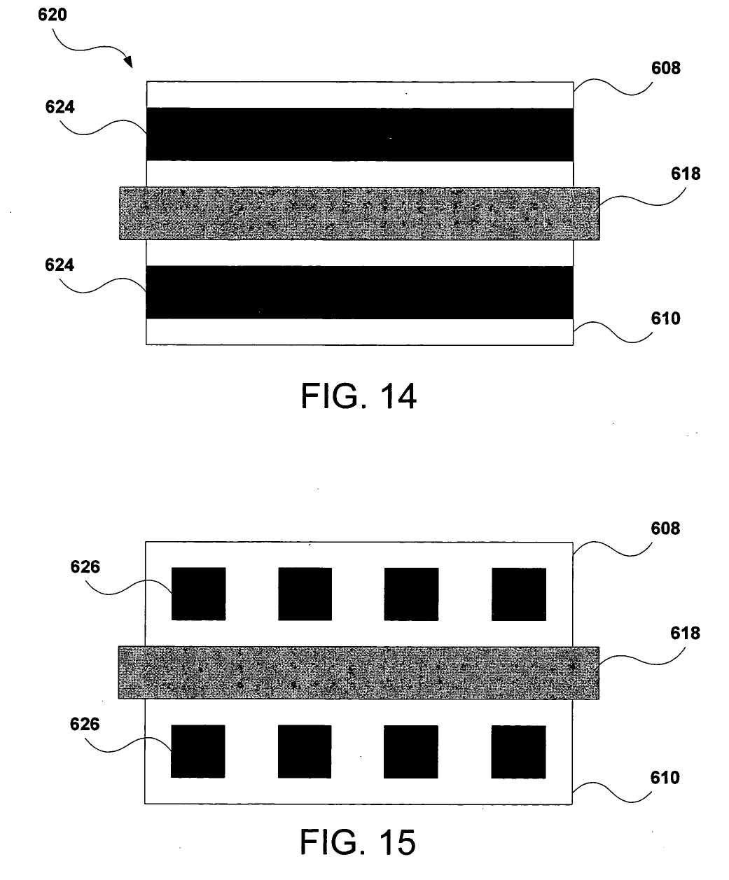

In implementations of the invention, each contact trench 624 extends across the length of the source region 608 or the drain region 610 upon which it is formed in a direction that is parallel to the metal gate 618. This is more clearly shown in FIG. 14, which provides a top view of the high-k/metal gate transistor 620 illustrating how each contact trench 624 extends across the source region 608 or the drain region 610. The contact trenches 624 run parallel to the metal gate 618. The use of contact trenches 624 allows later formed electrical contacts to the high-k/metal gate transistor 620 to extend across and fully strap the source and drain regions 608/610. This differs from conventional, discrete contact vias as shown in FIG. 15. The top view of the high-k/metal gate transistor 620 provided in FIG. 15 illustrates a number of discrete contact vias 626 that are lined up across the source region 608 or the drain region 610. In alternate implementations of the invention, however, such contact vias 626 may be used instead of contact trenches 624.

Conventional photolithographic processes may be used to form the contact trenches. For instance, one photolithography technique that may be used includes depositing a photoresist material onto the second dielectric layer, exposing the photoresist material to ultraviolet radiation using a patterned mask, developing the photoresist material, etching the second and first dielectric layers, and then removing the photoresist material. The photoresist material that remains after development functions as a mask to allow only selected portions of the dielectric layers to be etched, thereby defining structures such as the contact trenches.

After the contact trenches are formed, a metal layer, such as a nickel layer, may be deposited atop the second dielectric layer and within the contact trenches (526). Conventional deposition processes such as sputtering, PVD, CVD, or ALD may be used to deposit the nickel layer into the contact trenches. The deposition may be a conformal deposition. FIG. 11 illustrates the deposition of a nickel metal layer 628 onto the second dielectric layer 622 and within the contact trenches 624. As shown, the conformal deposition of the nickel layer 628 may cover the sidewalls and bottom surfaces of the contact trenches 624. In other implementations, alternate metals that may be used to form silicide layers over the source and drain regions include, but are not limited to, titanium, cobalt, and platinum.

An annealing process may then be carried out to cause the nickel and silicon to react and form nickel silicide layers over the source and drain regions (528). As described above, nickel silicide layers may improve the reliability of the high-k/metal gate transistor and may decrease the electrical resistance between the source/drain regions and the later formed electrical contacts. In one implementation, the annealing process for the nickel metal may use a temperature that is greater than or equal to 300° C. and is less than or equal to 500° C. The annealing process may last for a time period that ranges from milliseconds to a few seconds. In alternate implementations where titanium, cobalt, or platinum is used, the annealing process forms titanium silicide layers, cobalt silicide layers, or platinum silicide layers.

Unlike conventional silicide layers, the nickel silicide layers of the invention do not cover the entire surface of either the source region or the drain region. Because the deposited nickel layer is confined within the contact trenches, the formation of each nickel silicide layer is limited to the bottom surface of each contact trench. Accordingly, the surface area that is covered by the nickel silicide layer is confined to the surface area of the bottom of the contact trenches. Furthermore, the nickel silicide layer may at least partially diffuse into selected portions of the source region or the drain region. Thus, it is contemplated that the nickel silicide layer may consume a portion of the source/drain regions.

The unreacted nickel metal that remains, such as the nickel deposited on the sidewalls of the contact trenches and on the top surface of the second dielectric layer, may be selectively removed (530). In some implementations, a targeted wet etch process using sulfuric acid may be used to remove the unreacted nickel metal.

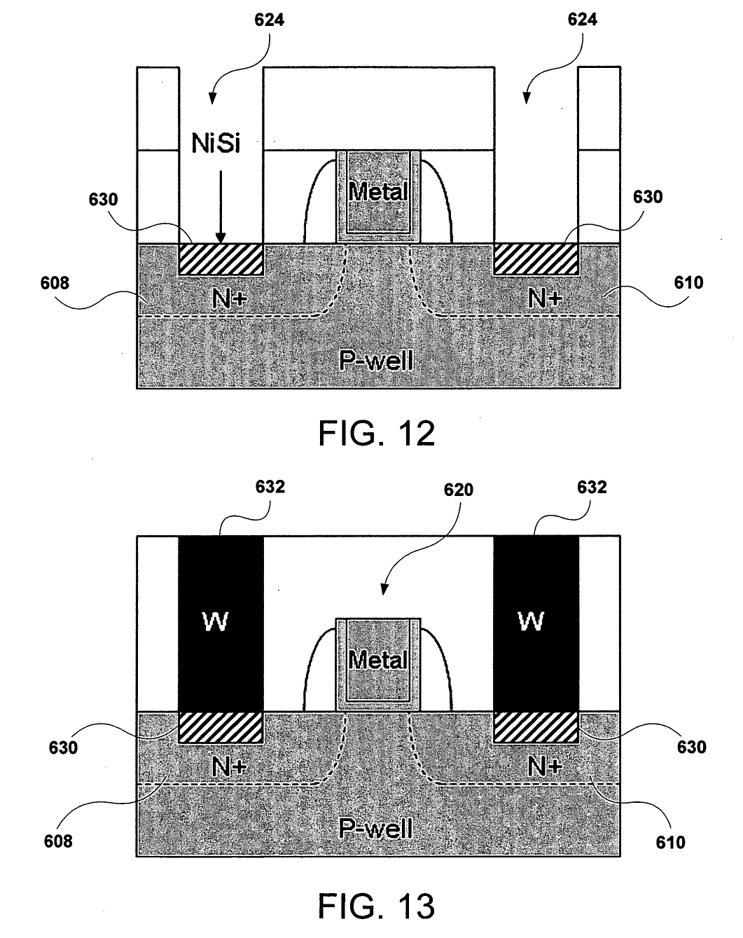

FIG. 12 illustrates a pair of nickel silicide layers 630 that have been formed over the source region 608 and the drain region 610. The unreacted nickel metal 628 has been selectively removed, leaving only the nickel silicide layers 630 behind. As shown, the nickel silicide layers 630 are confined to the bottom of the contact trenches 624 and do not cover the entire surface of either the source region 608 or the drain region 610.

After the nickel silicide layers are formed, a metallization process may be carried out to fill the contact trenches with metal that functions as electrical contacts to the high-k/metal gate transistor (532). In some implementations, the metal used to fill the contact trenches may be tungsten. In other implementations, metals that may be used to form the electrical contact include, but are not limited to, copper, ruthenium, palladium, platinum, cobalt, nickel, ruthenium oxide, tungsten, aluminum, titanium, tantalum, titanium nitride, tantalum nitride, hafnium, zirconium, a metal carbide, and a conductive metal oxide. Conventional metal deposition processes such as sputtering, PVD, CVD, ALD, electroless plating, or electroplating may be used to deposit metal into the contact trenches. The metallization process may be followed by a CMP process to remove any excess metal (534) and confine the metal deposition to the contact trenches.

FIG. 13 illustrates the metallized contact trenches, which form a pair of electrical contacts 632 to and from the high-k/metal gate transistor 620. These electrical contacts 632 couple the high-k/metal gate transistor 620 to interconnects or other devices (not shown). And as shown, the electrical contacts 632 include nickel silicide layers 630 that reduce electrical resistance between the electrical contacts 632 and the source and drain regions 608/610, while improving the reliability of the high-k/metal gate transistor 620.

Accordingly, a process flow to form nickel silicide layers in conjunction with a high-k/metal gate transistor has been described. The methods of the invention enable such an anneal to be applied to a high-k dielectric layer without damaging any high temperature intolerant metal that may be used in the metal gate electrode or metal silicide layer of the transistor.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method comprising:
forming a transistor with a sacrificial gate on a substrate;
depositing a first ILD layer on the substrate;
removing the sacrificial gate to form a gate trench;
depositing a high-k dielectric layer within the gate trench;
annealing the high-k dielectric layer;
depositing a first metal layer within the gate trench;
depositing a second ILD layer on the first ILD layer and the transistor;
etching the first and second ILD layers to form a first contact trench that extends to a source region of the transistor and a second contact trench that extends to a drain region of the transistor;
depositing a second metal layer within the contact trenches;
annealing the second metal layer to cause the second metal layer to react and form metal silicide layers on the source and drain regions; and
depositing a third metal layer within the first and second contact trenches to fill the contact trenches.

2. The method of claim 1, wherein the substrate comprises a semiconductor wafer.

3. The method of claim 1, wherein the sacrificial gate comprises polysilicon.

4. The method of claim 1, wherein the transistor further comprises a first spacer and a second spacer formed on laterally opposing sides of the sacrificial gate, wherein the source region is proximate to the first spacer and the drain region is proximate to the second spacer.

5. The method of claim 1, wherein the first ILD layer comprises SiO₂, CDO, silicon nitride, PFCB, or FSG.

6. The method of claim 1, wherein the depositing of the first ILD layer comprises depositing the first ILD layer using a process selected from the group consisting of PVD, CVD, ALD, PECVD, and epitaxial.

7. The method of claim 3, wherein the removing of the sacrificial gate comprises using a wet etch process or a dry etch process to selectively remove the polysilicon.

8. The method of claim 1, wherein the high-k dielectric layer comprises hafnium oxide, hafnium silicon oxide, hafnium silicon oxynitride, lanthanum oxide, zirconium oxide, zirconium silicon oxide, tantalum oxide, titanium oxide, barium strontium titanium oxide, BST, barium titanium oxide, strontium titanium oxide, yttrium oxide, aluminum oxide, lead scandium tantalum oxide, lead zinc niobate, or PZT.

9. The method of claim 1, wherein the depositing of the high-k dielectric layer comprises depositing the high-k dielectric layer using a process selected from the group consisting of CVD, low pressure CVD, PECVD, PVD, ALD, SOD, and epitaxial.

10. The method of claim 1, wherein the annealing of the high-k dielectric layer comprises annealing the high-k dielectric layer using a rapid thermal anneal at a temperature greater than or equal to 600° C. and less than or equal to 800° C.

11. The method of claim 10, wherein the annealing of the high-k dielectric layer further comprises annealing the high-k dielectric layer for a time period that ranges from 0.5 seconds to 10 seconds.

12. The method of claim 1, wherein the first metal layer comprises a metal selected from the group consisting of copper, ruthenium, palladium, platinum, cobalt, nickel, ruthenium oxide, tungsten, aluminum, titanium, tantalum, titanium nitride, tantalum nitride, hafnium, zirconium, a metal carbide, and a conductive metal oxide.

13. The method of claim 1, wherein the depositing of the first metal layer comprises depositing the first metal layer using a process selected from the group consisting of CVD, PVD, ALD, sputtering, electroplating, and electroless plating.

14. The method of claim 1, further comprising planarizing the first metal layer after the first metal layer has been deposited.

15. The method of claim 1, wherein the second ILD layer comprises SiO₂, CDO, silicon nitride, PFCB, or FSG.

16. The method of claim 1, wherein the depositing of the second ILD layer comprises depositing the second ILD layer using a process selected from the group consisting of PVD, CVD, ALD, PECVD, and epitaxial.

17. The method of claim 1, wherein the etching of the first and second ILD layers comprises using a photolithography process to etch the first and second ILD layers.

18. The method of claim 1, wherein the first and second contact trenches fully strap the source and drain regions.

19. The method of claim 1, wherein the second metal layer comprises a metal selected from the group consisting of nickel, titanium, cobalt, and platinum.

20. The method of claim 1, wherein the depositing of the second metal layer comprises depositing the second metal layer using a process selected from the group consisting of CVD, PVD, ALD, sputtering, electroplating, and electroless plating.

21. The method of claim 1, wherein the annealing of the second metal layer comprises annealing the second metal layer at a temperature that is greater than or equal to 300° C. and less than or equal to 500° C.

22. The method of claim 21, wherein the annealing of the second metal layer further comprises annealing the second metal layer for a time period of milliseconds to a few seconds.

23. The method of claim 1, further comprising selectively removing unreacted portions of the second metal layer.

24. The method of claim 1, wherein the third metal layer comprises a metal selected from the group consisting of copper, ruthenium, palladium, platinum, cobalt, nickel, ruthenium oxide, tungsten, aluminum, titanium, tantalum, titanium nitride, tantalum nitride, hafnium, zirconium, a metal carbide, and a conductive metal oxide.

25. The method of claim 1, wherein the depositing of the third metal layer comprises depositing the third metal layer using a process selected from the group consisting of CVD, PVD, ALD, sputtering, electroplating, and electroless plating.

26. The method of claim 1, further comprising planarizing the third metal layer after the third metal layer has been deposited.

27. A method comprising:
providing a transistor on a substrate, wherein the transistor includes an annealed high-k gate dielectric and a metal gate;
depositing a an ILD layer over the substrate and the transistor;
etching the ILD layer to form a first contact trench that extends to a source region of the transistor and a second contact trench that extends to a drain region of the transistor;
depositing a metal layer within the first and second contact trenches;
annealing the metal layer to cause the metal layer to react and form metal silicide layers that are disposed on the source and drain regions and confined to the bottom of the first and second contact trenches; and
filling the first and second contact trenches with a second metal layer.

28. The method of claim 27, wherein the annealed high-k gate dielectric comprises a high-k dielectric selected from the group consisting of hafnium oxide, hafnium silicon oxide, hafnium silicon oxynitride, lanthanum oxide, zirconium oxide, zirconium silicon oxide, tantalum oxide, titanium oxide, barium strontium titanium oxide, BST, barium titanium oxide, strontium titanium oxide, yttrium oxide, aluminum oxide, lead scandium tantalum oxide, lead zinc niobate, and PZT.

29. The method of claim 27, wherein the metal gate comprises a metal selected from the group consisting of copper, ruthenium, palladium, platinum, cobalt, nickel, ruthenium oxide, tungsten, aluminum, titanium, tantalum, titanium nitride, tantalum nitride, hafnium, zirconium, a metal carbide, and a conductive metal oxide.

30. The method of claim 27, wherein the ILD layer comprises a dielectric material selected from the group consisting of SiO₂, CDO, silicon nitride, PFCB, and FSG.

31. The method of claim 27, wherein the metal layer comprises a metal selected from the group consisting of nickel, titanium, and cobalt.

32. The method of claim 27, wherein the second metal layer comprises a metal selected from the group consisting of copper, ruthenium, palladium, platinum, cobalt, nickel, ruthenium oxide, tungsten, aluminum, titanium, tantalum, titanium nitride, tantalum nitride, hafnium, zirconium, a metal carbide, and a conductive metal oxide.

33. The method of claim 27, further comprising selectively removing unreacted portions of the metal layer.

34. The method of claim 27, wherein the annealing of the metal layer comprises annealing the metal layer at a temperature that is greater than or equal to 300° C. and less than or equal to 500° C. for a time period of milliseconds to a few seconds.

35. The method of claim 27, further comprising planarizing the second metal layer.

36. An apparatus comprising:
an annealed high-k gate dielectric;
a metal gate disposed upon the annealed high-k gate dielectric;
a first spacer and a second spacer formed on laterally opposite sides of the metal gate;
a source region proximate to the first spacer;
a first metal silicide layer disposed on the source region;
a drain region proximate to the second spacer; and
a second metal silicide layer disposed on the drain region.

37. The apparatus of claim 36, further comprising:
a first electrical contact coupled to the first metal silicide layer; and
a second electrical contact coupled to the second metal silicide layer.

38. The apparatus of claim 36, wherein the annealed high-k gate dielectric comprises a high-k dielectric selected from the group consisting of hafnium oxide, hafnium silicon oxide, hafnium silicon oxynitride, lanthanum oxide, zirconium oxide, zirconium silicon oxide, tantalum oxide, titanium oxide, barium strontium titanium oxide, BST, barium titanium oxide, strontium titanium oxide, yttrium oxide, aluminum oxide, lead scandium tantalum oxide, lead zinc niobate, and PZT.

39. The apparatus of claim 36, wherein the metal gate comprises a metal selected from the group consisting of copper, ruthenium, palladium, platinum, cobalt, nickel, ruthenium oxide, tungsten, aluminum, titanium, tantalum, titanium nitride, tantalum nitride, hafnium, zirconium, a metal carbide, and a conductive metal oxide.

40. The apparatus of claim 36, wherein the first spacer and the second spacer comprise silicon nitride.

41. The apparatus of claim 36, wherein the metal silicide layer includes a metal selected from the group consisting of nickel, titanium, cobalt, and platinum.

42. The apparatus of claim 36, wherein the electrical contacts comprise a metal selected from the group consisting of copper, ruthenium, palladium, platinum, cobalt, nickel, ruthenium oxide, tungsten, aluminum, titanium, tantalum, titanium nitride, tantalum nitride, hafnium, zirconium, a metal carbide, and a conductive metal oxide.
